(19) United States
(12) Patent Application Publication
(10) Pub. No.: US 2025/0343057 A1
(43) Pub. Date: Nov. 6, 2025

(54) STAGE AND SUBSTRATE TREATMENT APPARATUS INCLUDING THE SAME

(71) Applicant: SAMSUNG ELECTRONICS CO., LTD., SUWON-SI (KR)

(72) Inventors: DASOM LEE, Suwon-si (KR); MINSUNG KIM, Suwon-si (KR); SUDONG MOON, Suwon-si (KR); HAN SANG KIM, Suwon-si (KR); WANGI CHA, Suwon-si (KR); HAKJONG YU, Suwon-si (KR)

(21) Appl. No.: 19/071,816

(22) Filed: Mar. 6, 2025

(30) Foreign Application Priority Data
May 2, 2024 (KR) 10-2024-0058771

(51) Int. Cl. H01L 21/67; H01L 21/683

(52) U.S. Cl. CPC H01L 21/67069; H01L 21/67098; H01L 21/6831

(57) ABSTRACT

A stage including: a body portion configured to support a substrate, wherein the body portion includes a flow path; and a peripheral device, at least a part of which is located inside the body portion, wherein the part of the peripheral device is positioned at the same height as the flow path and overlaps the flow path when viewed from above, wherein the flow path is partitioned by a flow path partition wall, wherein the part of the peripheral device is surrounded by an internal element partition and included within an internal space of the internal element partition, wherein a thickness of the flow path partition wall is smaller than a maximum width of the internal space in a direction perpendicular to a side of the flow path partition wall.

### CROSS-REFERENCE TO RELATED APPLICATION

This application claims priority under 35 U.S.C. § 119 to Korean Patent Application No. 10-2024-0058771, filed on May 2, 2024, in the Korean Intellectual Property Office, the disclosure of which is incorporated by reference herein in its entirety.

### TECHNICAL FIELD

The present disclosure relates to a stage and a substrate treatment apparatus including the same, and more particularly to a stage with a fluid flow path and a substrate treatment apparatus that includes such a stage.

### DISCUSSION OF RELATED ART

As semiconductor line widths decrease, semiconductor patterns are evolving into narrow and deep high aspect ratio structures. To achieve this, the importance of etching processes performed at cryogenic temperatures is gaining attention. Lowering the process temperature to cryogenic levels can reduce lateral etching by decreasing chemical reactivity, thereby enabling the formation of high aspect ratio semiconductor patterns. Therefore, various studies are being conducted on substrate treatment apparatus capable of performing processes at cryogenic temperatures.

### SUMMARY

Embodiments of the present disclosure provide a stage that expands the flow path when viewed from above, and a substrate treatment apparatus including the same.

Embodiments of the present disclosure provide a stage that increases the heat transfer rate between the flow path and the substrate, and a substrate treatment apparatus including the same.

Embodiments of the present disclosure provide a stage that improves the temperature distribution of a substrate and a substrate treatment apparatus including the same.

According to an example embodiment, there is provided a stage including: a body portion configured to support a substrate, wherein the body portion includes a flow path; and a peripheral device, at least a part of which is located inside the body portion, wherein the part of the peripheral device is positioned at the same height as the flow path and overlaps the flow path when viewed from above, wherein the flow path is partitioned by a flow path partition wall, wherein the part of the peripheral device is surrounded by an internal element partition and included within an internal space of the internal element partition, wherein a thickness of the flow path partition wall is smaller than a maximum width of the internal space in a direction perpendicular to a side of the flow path partition wall.

According to an example embodiment, there is provided a substrate treating apparatus including: a chamber in which a processing space for processing a substrate is formed; and a stage configured to support a substrate in the processing space, wherein the stage includes: a body portion configured to place the substrate on an upper surface thereof, wherein the body portion includes a flow path; and a peripheral device, at least a part of which is located inside the body portion, wherein the part of the peripheral device is positioned at the same height as the flow path and overlaps the flow path when viewed from above, wherein the flow path is partitioned by a flow path partition wall, wherein the part of the peripheral device is surrounded by an internal element partition and included within an internal space of the internal element partition, wherein a thickness of the flow path partition wall is smaller than a maximum width of the internal space in a direction perpendicular to a side of the flow path partition wall.

According to an example embodiment, there is provided

A substrate treating apparatus including: a chamber in which a processing space for processing a substrate is formed; a stage configured to support a substrate in the processing space; and a treating fluid supply portion configured to supply a treating fluid for processing the substrate to the processing space, wherein the stage includes: a body portion configured to place a substrate on an upper surface thereof, wherein the body portion includes a flow path; and a peripheral device, at least a part of which is located inside the body portion, wherein the part of the peripheral device is positioned at the same height as the flow path and overlaps the flow path when viewed from above, wherein the flow path is partitioned by a flow path partition wall, wherein the part of the peripheral device is surrounded by an internal element partition and included within an internal space of the internal element partition, wherein a thickness of the flow path partition wall is smaller than a maximum width of the internal space in a direction perpendicular to a side of the flow path partition wall.

### BRIEF DESCRIPTION OF DRAWINGS

The above and other features of the present disclosure will be more clearly understood from the following detailed description, taken in conjunction with the accompanying drawings.

FIG. 1 is a block diagram illustrating a substrate treatment apparatus according to an example embodiment of the present disclosure.

FIG. 2 is a vertical cross-sectional view illustrating an example of the stage illustrated in FIG. 1.

FIG. 3 is a horizontal cross-sectional view illustrating an example of a flow path of the stage illustrated in FIG. 2.

FIG. 4 is an enlarged horizontal cross-sectional view of the center of the stage illustrated in FIG. 3.

FIG. 5 is a horizontal cross-sectional view illustrating an internal element partition according to an example embodiment of the present disclosure.

FIG. 6 is a vertical cross-sectional view illustrating an example of a flow path of a stage according to an example embodiment of the present disclosure.

FIG. 7 is a vertical cross-sectional view illustrating an example of the heat transfer post illustrated in FIG. 6.

FIG. 8 is a perspective view illustrating an example of a first heat transfer post illustrated in FIG. 6.

FIG. 9 is a perspective view illustrating an example of a second heat transfer post illustrated in FIG. 6.

FIG. 10 is a horizontal cross-sectional view illustrating an example of a flow path of a stage according to an example embodiment of the present disclosure.

FIG. 11 is a vertical cross-sectional view illustrating a stage according to an example embodiment of the present disclosure.

FIG. 12 is a vertical cross-sectional view illustrating a stage according to an example embodiment of the present disclosure.

### DETAILED DESCRIPTION OF THE EMBODIMENTS

Hereinafter, embodiments of the present disclosure will be described in detail and with sufficient clarity for those skilled in the art to easily implement the invention.

In this specification, “inside” refers to the direction toward the body when the present disclosure is worn, and “outside” refers to the opposite direction of the inside.

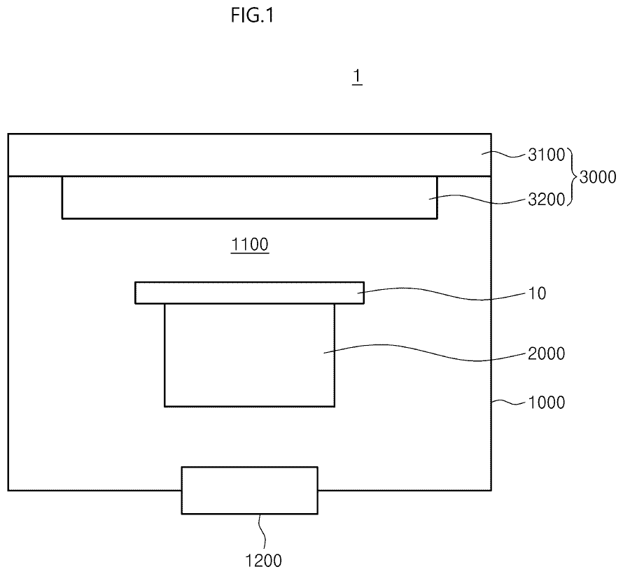

FIG. 1 is a block diagram illustrating a substrate treating apparatus 1 according to an example embodiment of the present disclosure. The substrate treating apparatus 1 may also be referred to as a substrate treatment apparatus.

Referring to FIG. 1, the substrate treating apparatus 1 may include a chamber 1000, a stage 2000, and a treating fluid supply portion 3000. The treating fluid supply portion 3000 may be referred to as a treatment fluid supply portion.

The substrate treating apparatus 1 may perform a process on a substrate 10 in a cryogenic temperature range. For example, the process may be a cryogenic etching process, a cryogenic deposition process, etc. Here, the cryogenic temperature range is −20° C. to −170° C., more particularly −40° C. to −170° C. When performing a cryogenic etching process according to an example embodiment of the present disclosure, an ideal vertical etch profile may be achieved when etching a high aspect ratio structure on the objected to be etched.

The substrate 10 may be provided as a wafer or glass, etc. The substrate 10 may have a disk structure of various diameters. According to an example embodiment, the substrate 10 may be provided in a disk structure with a radius of 150 mm. However, the shape of the substrate 10 is not limited to this and may be provided in different shapes and/or sizes.

The chamber 1000 may include a processing space 1100 therein. The substrate 10 may be processed within the processing space 1100. The chamber 1000 may isolate the stage 2000 from the external environment and create a vacuum environment in the processing space 1100. In addition, the chamber 1000 may include openings in areas connected to a pumping connection portion 1200, which is connected to a vacuum system, and a plasma supply portion 3100. The size of the opening connected to the pumping connection portion 1200 and the size of the opening connected to the plasma supply portion 3100 may be different from each other.

The vacuum system connected to the pumping connection 1200 may include a high vacuum pump such as a turbo-molecular pump, a low vacuum pump such as a dry pump, and/or various valves, etc. The vacuum system may exhaust air inside the chamber 1000 to create a vacuum environment inside the processing space 1100.

The stage 2000 may support the substrate 10 in the processing space 1100. The stage 2000 may be provided as an electrostatic chuck (ESC) capable of fixing and supporting the substrate 10 by electrostatic force. The stage 2000 may control the temperature and temperature uniformity of the substrate 10.

The treating fluid supply portion 3000 may supply treating fluid to the processing space 1100. The treating fluid is a fluid that reacts with the substrate 10 and treats the substrate 10. According to an example embodiment, the treating fluid supply portion 3000 may include the plasma supply portion 3100 and a gas supply portion 3200.

The plasma supply portion 3100 may supply plasma for processing the substrate 10 into the processing space 1100. The plasma supply portion 3100 may be coupled to a corresponding one of the openings formed in the chamber 1000. The plasma supply portion 3100 is a reactive ion etching source (for example, a capacitively coupled plasma (CCP) source in the form of a plate), an Inductively Coupled Plasma (ICP) source in the form of a coil-based antenna, or an Electron Cyclotron Resonance (ECR) source, etc.

The gas supply portion 3200 may be combined with the plasma supply portion 3100 and inject treating (treatment) gas or processing gas into the processing space 1100 through an injection port, such as a nozzle or showerhead. To ensure uniform injection of the treating gas or processing gas into the processing space 1100, the gas supply portion 3200 may be composed of a single zone or a plurality of zones. The gas supplied by gas supply portion 3200 may be generated as plasma by the plasma supply portion 3100 in the processing space 1100. In contrast, the gas supplied by the gas supply portion 3200 may be generated as plasma by the plasma supply portion 3100 and then supplied to the processing space 1100.

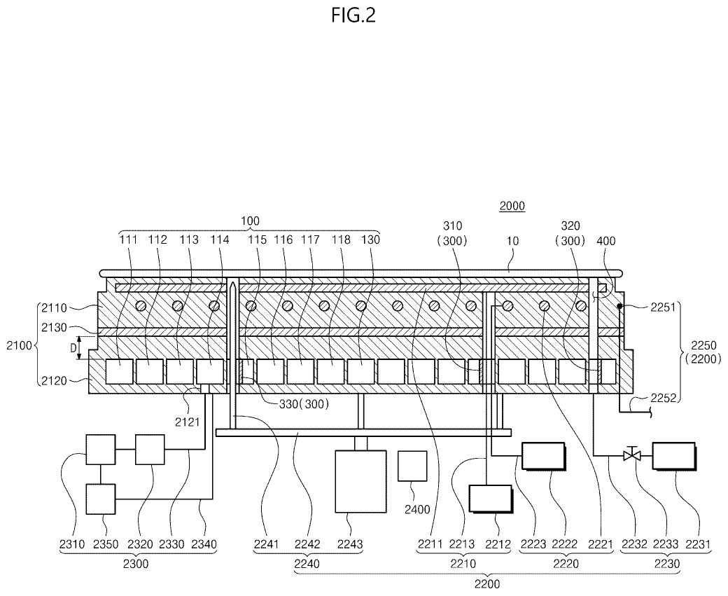

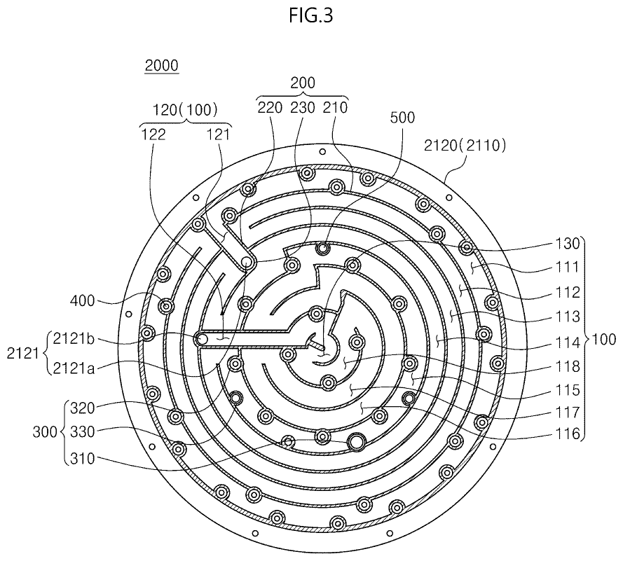

FIG. 2 is a vertical cross-sectional view illustrating an example of the stage 2000 illustrated in FIG. 1. FIG. 3 is a horizontal cross-sectional view illustrating an example of a flow path 100 of the stage 2000 illustrated in FIG. 2. Referring to FIGS. 2 and 3, according to an example embodiment, the stage 2000 may include a body portion 2100, a peripheral device 2200, a fluid supply portion 2300, and a control portion 2400. The control portion 2400 may also be referred to as a controller.

The substrate 10 may be placed on the upper surface of the body portion 2100. A flow path 100 may be formed inside the body portion 2100. Fluid may flow in the flow path 100. According to an example embodiment, the body portion 2100 may include an upper body 2110, a lower body 2120, and a joint portion 2130.

An upper surface of the upper body 2110 may directly support the substrate 10. According to an example embodiment, the substrate 10 may be fixed on the upper surface of the upper body 2110 by electrostatic force. The upper body 2110 may be made of dielectric material. The dielectric material may be ceramic. For example, the dielectric material may be alumina (Al₂O₃) or aluminum nitride (AlN).

The diameter of the upper surface of the upper body 2110 may be the same as or smaller than the diameter of the substrate 10. The diameter of the upper surface of the upper body 2110 may range from 95.0% to 100% of the diameter of the substrate 10. When the diameter of the upper surface of the upper body 2110 is less than 95.0% of the diameter of the substrate 10, the heat transfer rate between the edge area of the substrate 10 and the upper surface of the upper body 2110 decreases, making it difficult to control the temperature of the edge area of the substrate 10. When the diameter of the upper surface of the upper body 2110 exceeds 100% of the diameter of the substrate 10, the distance between an edge ring and the substrate 10 may increase (when the edge ring is provided), reducing the effectiveness of the edge ring. The edge ring surrounds the substrate 10 placed on the upper surface of the upper body 2110. For example, when the diameter of the substrate 10 is 300 mm, the diameter of the upper surface of the upper body 2110 may be 300 mm or less (for example, 296 mm to 298 mm, etc.). For example, the diameter of the upper surface of the upper body 2110 may be 297 mm.

Additionally, the thickness of the upper body 2110 may be 0.3 mm to 10 mm. For example, the thickness of the upper body 2110 may be 1 mm. If the thickness of the upper body 2110 is less than 0.3 mm, the upper body 2110 may be susceptible to damage when high voltage is applied to its components. Additionally, if the thickness of the upper body 2110 exceeds 10 mm, the impedance of the upper body 2110 increases, potentially causing damage to components affected by the increased impedance.

The lower body 2120 may be located below the upper body 2110. According to an example embodiment, the flow path 100 may be formed within the lower body 2120.

The lower body 2120 is made of not only from aluminum (Al), commonly used as a chuck body material, but also from a metal-based material with a coefficient of thermal expansion (CTE) closer to that of the ceramic used for the upper body (2110) than aluminum (Al). According to an example embodiment, the lower body 2120 may be made of titanium (Ti), which helps prevent damage to the body portion 2100 caused by a difference in thermal expansion rates between the upper body 2110 and the lower body 2120.

The lower body 2120 may be manufactured using metal 3D printing. Therefore, even when the lower body 2120 is made of a metal material (e.g., titanium (Ti)), which is more difficult to cut than aluminum (Al), the shape of the lower body 2120 in which the flow path 100, etc. is formed may be more easily implemented.

The joint portion 2130 is located between the upper body 2110 and the lower body 2120. The joint portion 2130 may join the upper body 2110 and the lower body 2120 to each other. In other words, the joint portion 2130 may connect the upper body 2110 and the lower body 2120 to each other with electrically low resistance. Additionally, the joint portion 2130 may mechanically join the upper body 2110 and the lower body 2120 to each other.

The peripheral device 2200 may include a component located inside the body portion 2100 among the elements constituting the stage 2000. According to an example embodiment, the peripheral device 2200 may include an electrostatic chuck 2210, a heater 2220, a heat transfer gas supply portion 2230, a lift pin unit 2240, and a temperature measurement portion 2250. At least a portion of the peripheral device 2200 may be provided at substantially the same height as the flow path 100. When viewed from above, this portion of the peripheral device 2200 may overlap the flow path 100.

The electrostatic chuck 2210 may generate electrostatic force to secure the substrate 10 to the upper surface of the upper body 2110. According to an example embodiment, the electrostatic chuck 2210 may include an electrostatic electrode 2211, a chucking power supply portion 2212, and a chucking power connection portion 2213.

The electrostatic electrode 2211 may be provided in the upper body 2110. According to an example embodiment, the electrostatic electrode 2211 may be disposed above a heating electrode 2221. The electrostatic electrode 2211 may be electrically connected to the chucking power supply portion 2212 via the chucking power connection portion 2213. The electrostatic electrode 2211 may be formed in a specific patterned shape. For example, the electrostatic electrode 2211 may be provided in a circular or spiral structure when viewed from above. The electrostatic electrode 2211 may be monopolar or bipolar. The electrostatic electrode 2211 may be made of a material selected based on properties such as thermal expansion coefficient and electrical conductivity within cryogenic temperature ranges. For example, the electrostatic electrode 2211 may be made of a metal such as tungsten (W) and/or molybdenum (Mo), or an alloy containing these metals.

The chucking power supply portion 2212 may include a filter and a direct current or alternating current power supply. The chucking power supply portion 2212 may apply direct current (DC) or alternating current (AC) power to the electrostatic electrode 2211. According to an example embodiment, the chucking power supply portion 2212 may be located outside the body portion 2100.

When the chucking power supply portion 2212 applies power to the electrostatic electrode 2211, the substrate 10 may be fixed to the upper body 2110 by Coulomb force, Johnson Rahbek Force or a mixture of Coulomb force and Johnson-Rabeck force depending on the resistivity of the upper body 2110.

The chucking power connection portion 2213 electrically connects the electrostatic electrode 2211 and the chucking power supply portion 2212. The chucking power connection portion 2213 may penetrate the body portion 2100 and be connected between the electrostatic electrode 2211 and the chucking power supply portion 2212.

According to an example embodiment, the chucking power connection portion 2213 may sequentially pass through the lower body 2120 and the upper body 2110 from the bottom of the lower body 2120 and be connected to the electrostatic electrode 2211. The chucking power connection portion 2213 may be configured in a cable structure. In this case, at least a part of the chucking power connection portion 2213 may pass through flow path 100 in the vertical direction.

The heater 2220 may heat the substrate 10 to a predetermined temperature. According to an example embodiment, the heater 2220 may include the heating electrode 2221, a heating power supply portion 2222, and a heating power connection portion 2223.

The heating electrode 2221 may be provided in the upper body 2110. According to an example embodiment, the heating electrode 2221 may be disposed below the electrostatic electrode 2211. For example, the heating electrode 2221 may be overlapped by the electrostatic electrode 2211 in the vertical direction. The heating electrode 2221 is electrically connected to the heating power supply portion 2222. The heating electrode 2221 may be formed in a specific patterned shape. For example, the heating electrode 2221 may be provided in a circular or spiral coil structure when viewed from above. Additionally, the heating electrode 2221 may be made of a material determined based on characteristics such as thermal expansion coefficient and electrical conductivity in the cryogenic temperature range. For example, the electrostatic electrode 2211 may be made of a metal such as tungsten (W) and/or molybdenum (Mo), or an alloy containing these metals.

The heating power supply portion 2222 may include a filter and a direct current or alternating current power supply. The heating power supply portion 2222 may apply direct current (DC) or alternating current (AC) power to the heating electrode 2221. According to an example embodiment, the heating power supply portion 2222 may be located outside the body portion 2100.

When the heating power supply portion 2222 applies power to the heating electrode 2221, the heating electrode 2221 generates heat by resisting the current of the applied power. The generated heat is transferred to the substrate 10 through the upper body 2110 and heats the substrate 10 to a predetermined temperature.

The heating power connection portion 2223 electrically connects the heating electrode

2221 and the heating power supply portion 2222. The heating power connection portion 2223 may penetrate the body portion 2100 to be connected between the heating electrode 2221 and the heating power supply portion 2222. According to an example embodiment, the heating power connection portion 2223 may sequentially pass through the lower body 2120 and the upper body 2110 from the bottom of the lower body 2120 and be connected to the heating electrode 2221. The heating power connection 2223 may be provided in a cable structure. According to an example embodiment, when viewed from above, the heating power connection portion 2223 may pass through an area closer to the edge of the lower body 2120 than the area where the flow path 100 is located. However, at least a part of the heating power connection portion 2223 may pass vertically through the flow path 100.

The heat transfer gas supply portion 2230 may supply heat transfer gas to the space between the substrate 10 and the upper surface of the upper body 2110. The heat transfer gas supplied between the substrate 10 and the upper body 2110 improves the transfer efficiency of heat transfer from the upper body 2110 to the substrate 10. According to an example embodiment, the heat transfer gas supply portion 2230 may include a gas storage 2231, a gas supply line 2232, and a valve 2233.

The gas storage 2231 stores heat transfer gas. The heat transfer gas may include an inert gas. For example, the heat transfer gas may be provided as a single type of inert gas such as Helium (He), Argon (Ar), or Nitrogen (N2), or a mixture of these inert gases. According to an example embodiment, the gas storage 2231 may be provided outside the body portion 2100.

The heat transfer gas stored in the gas storage 2231 may be supplied between the substrate 10 and the upper surface of the upper body 2110 through a heat transfer gas flow path 400 provided in the body portion 2100. The gas supply line 2232 connects the gas storage 2231 and the heat transfer gas flow path 400, allowing the heat transfer gas to flow through. The gas supply line 2232 may be opened and closed by the valve 2233.

The lift pin unit 2240 may load the substrate 10 onto the upper surface of the upper body 2110 or unload the substrate 10 from the upper surface of the upper body 2110. According to an example embodiment, the lift pin unit 2240 may include a lift pin 2241, a support member 2242, and a pin driver 2243.

A plurality of lift pins 2241 may be provided. The lift pin 2241 is located in a pin movement path 500 provided in the body portion 2100 and may move in the up and down direction along the pin movement path 500. The top of the lift pin 2241 may support the substrate 10.

The support member 2242 may be located below lower body 2120. The support member 2242 supports the lift pin 2241.

The pin driver 2243 may lift and lower the support member 2242. As the support member 2242 moves in the vertical direction due to the driving of the pin driver 2243, the lift pins 2241 may move in the vertical direction along the pin movement paths 500. The pin driver 2243 may be located outside the body portion 2100.

The plasma supply portion 3100 may include an RF (radio frequency) power supply portion and an RF power matching potion. The RF power supply portion may supply power to generate plasma in the processing space 1100. The RF power matching potion may minimize power loss by matching the impedance between the RF power supply portion and components connected to the RF power supply portion.

The RF power supply portion and the RF power matching potion may be electrically connected to the body portion 2100 based on the method used for generating plasma by the plasma supply portion 3100. Alternatively, the RF power supply portion and the RF power matching potion may be electrically connected to either a component positioned above the body portion 2100 of the plasma supply portion 3100, or to both the component above the body portion 2100 and the body portion 2100 itself, depending on the plasma generation method employed by the plasma supply portion 3100.

The temperature measurement portion 2250 may measure the temperature and temperature uniformity of the body portion 2100. For example, the temperature measurement portion 2250 may measure the temperature and temperature uniformity of the upper body 2110 and/or the lower body 2120. The temperature measurement portion 2250 may transmit data about the measured temperature and temperature uniformity to the controller 2400. According to an example embodiment, the temperature measurement portion 2250 may include a thermometer 2251 and a data transmission line 2252.

A plurality of thermometers 2251 may be provided, each embedded at different positions in the body portion 2100. The thermometers 2251 may be provided as at least one of various types of thermometers capable of measuring the temperature of the body portion 2100. For example, the thermometers 2251 may be provided as a fluorescence thermometer (Fluoroptic®thermometry) or a thermocouple (TC) thermometer configured with a filter.

The data transmission line 2252 connects the thermometer 2251 and the controller 2400 so that a signal of the value measured from the thermometer 2251 is transmitted to the controller 2400. A portion of the data transmission line 2252 may be provided inside the body portion 2100. According to an example embodiment, the data transmission line 2252 may extend to bypass the flow path 100. Alternatively, the data transmission line 2252 may pass through the flow path 100 and be connected between the thermometers 2251 and the controller 2400.

The fluid supply portion 2300 may supply fluid to the flow path 100. The fluid supply portion 2300 may circulate fluid in the flow path 100. According to an example embodiment, the fluid circulating within the flow path 100 may be a cryogenic refrigerant for cooling the substrate 10. For example, the fluid may be provided as Galden® or Liquid Nitrogen (LN₂). The fluid supply portion 2300 may include a fluid storage 2310, a circulation driver 2320, and a fluid supply line 2330, a fluid recovery line 2340 and a temperature controller 2350.

The fluid storage 2310 may store fluid circulating in the flow path 100. According to an example embodiment, the fluid storage 2310 may include a dewar that stores cryogenic refrigerant.

The circulation driver 2320 may provide a driving force so that the fluid circulates inside the flow path 100. According to an example embodiment, the circulation driver 2320 may include a pump for supplying cryogenic liquid refrigerant. Fluid may pass through a fluid movement path 2121 formed in the lower body 2120 and circulate between the flow path 100 and the fluid storage 2310.

The fluid movement path 2121 may include a first fluid entrance hole 2121a and a second fluid entrance hole 2121b. Fluid may be supplied to the flow path 100 through the fluid supply line 2330 and one of the first fluid entrance hole 2121a and the second fluid entrance hole 2121b. The fluid circulating in the flow path 100 may be discharged from the flow path 100 through the other of the first fluid entrance hole 2121a and the second fluid entrance hole 2121b. For example, fluid supplied to the first fluid entrance hole 2121a may exit via the second fluid entrance hole 2121b. According to an example embodiment, the top of the first fluid entrance hole 2121a and the top of the second fluid entrance hole 2121b are connected to the flow path 100. The top of the first fluid entrance hole 2121a and the top of the second fluid entrance hole 2121b may be located between an outermost circumferential flow path 111 and a center flow path 130. The fluid discharged from the flow path 100 may be collected in the fluid storage 2310 through the fluid recovery line 2340.

The temperature controller 2350 may control the temperature of the fluid supplied to the flow path 100. According to an example embodiment, the temperature controller 2350 may include a cryogenic chiller. The fluid recovered through the fluid recovery line 2340 may be cooled to a cryogenic state by the temperature controller 2350 and supplied to the fluid storage 2310.

The controller 2400 may control the temperature of the substrate 10 and the temperature uniformity of the substrate 10. In other words, the controller 2400 may measure the temperature and temperature uniformity of the upper body 2110 using the temperature measurement portion 2250. Additionally, the controller 2400 may control the operation of the heater 2220, turning it on or off. The controller 2400 may also control the valve 2233 to adjust the gas supply from the heat transfer gas supply portion 2230. According to an example embodiment, the controller 2400 manages the heater 2220's on/off state and adjusts the heat transfer gas supply amount based on the measured temperature and temperature uniformity data to control the temperature and temperature uniformity of the substrate 10.

Each of the first fluid entrance hole 2121a and the second fluid entrance hole 2121b may be provided as a single unit. Additionally, the flow path 100 may be provided as a single path between the top of the first fluid entrance hole 2121a and the top of the second fluid entrance hole 2121b. The flow path 100 may be formed in a specific patterned shape. According to an example embodiment, the flow path 100 may include circumferential flow paths 111, 112, 113, 114, 115, 116, 117 and 118, a radial flow path 120, and a center flow path 130.

The circumferential flow paths 111 to 118 extend along the circumferential direction of the upper surface of the body portion 2100 when viewed from above. According to an example embodiment, when viewed from above, the circumferential flow paths 111 to 118 extend along the circumferential direction of the upper surface of the upper body 2110. A plurality of circumferential flow paths 111 to 118 may be provided. When viewed from above, circumferential flow paths 111 to 118 may be arranged along the radial direction of the upper surface of the upper body 2110. At least one of the circumferential flow paths 111 to 118 may be provided in multiple instances at the same radius. A plurality of circumferential flow paths arranged at the same radius may be distributed along the circumferential direction of the upper surface of the upper body 2110.

When viewed from above, the radial flow path 120 extends in the radial direction of the upper surface of the body portion 2100. According to an example embodiment, the radial flow path 120 extends along the radial direction of the upper surface of the upper body 2110 when viewed from above. The radial flow path 120 may include a first radial flow path 121 and a second radial flow path 122.

The radial flow path 120 may block circumferential flow paths 112 to 117 that intersect with it, while allowing the circumferential flow paths 111 and 118 to communicate with the radial flow path 120. According to an example embodiment, at the points where the circumferential flow paths 112 to 117 are blocked by the radial flow path 120, each of these blocked circumferential flow paths may be connected to another circumferential flow path located at a different radius on the upper surface of the upper body 2110.

The first radial flow path 121 connects the first fluid entrance hole 2121a to one 111 of the circumferential flow paths 111 to 118 and the center flow path 130. The second radial flow path 122 connects the second fluid entrance hole 2121b to the other one 118 of the circumferential flow paths 111 to 118 and the center flow path 130. According to an example embodiment, the first radial flow path 121 may connect the first fluid entrance hole 2121a to the outermost circumferential flow path 111. In addition, the second radial flow path 122 may connect the second fluid entrance hole 2121b to the circumferential flow path 118 closest to the center flow path 130.

When viewed from above, the center flow path 130 includes an area corresponding to the center of the upper surface of the body portion 2100 and is located further inside the body portion 2100 than the circumferential flow paths 111 to 118. According to an example embodiment, the center flow path 130 may be provided as a circular structure surrounding the center of the upper surface of the upper body 2110 when viewed from above.

According to an example embodiment, one end of each circumferential flow path 111 to 118 communicates with another circumferential flow path located at an adjacent radii of the body portion 2100, the adjacent radial flow path 120 and the center flow path 130. Similarly, the other end of each circumferential flow path 111 to 118 communicates with another circumferential flow path located at different adjacent radii of the body portion 2100, the adjacent radial flow path 120 and the center flow path 130.

The flow path 100 is partitioned by a flow path partition wall 200. According to an example embodiment, the circumferential flow paths 111 to 118, the first and second radial flow paths 121 and 122, and the center flow path 130 are partitioned by the flow path partition wall 200. The flow path partition wall 200 may include a circumferential partition wall 210, a radial partition wall 220, and a radial path end partition wall 230.

The circumferential partition wall 210 separates the circumferential flow paths 111 to 118 from each other. Additionally, the circumferential partition wall 210 separates the outermost circumferential partition wall 210 from the outside when viewed from above. Additionally, the circumferential partition wall 210 partitions the center flow path 130 from the closest the circumferential flow path 118. A plurality of circumferential partition walls 210 may be provided, arranged spaced apart from each other along the radial direction of the upper surface of the upper body 2110.

Communicating areas of the circumferential partition walls 210 between the circumferential flow paths 111 to 118, communicating areas of the circumferential partition walls 210 between the circumferential flow paths 111 and 118 corresponding to the radial flow paths 120 and communicating areas of the circumferential partition wall 210 between the circumferential flow path 118 and the center flow path 130 are open.

Each of the circumferential partition walls 210 has a uniform thickness.

The radial partition wall 220 separates each radial flow path 120 from the circumferential flow paths 112 to 117, which are blocked by the radial flow path 120. Additionally, the radial partition wall 220 partitions the ends of the circumferential flow paths 111, 115 to 118. The communicating area of the radial partition wall 220 between the first radial flow path 121 and the outermost circumferential flow path 111 is open. Additionally, the communicating area of the radial partition wall 220 between the second radial flow path 122 and the circumferential flow path 118, which is closest to the center flow path 130, is open.

The radial path end partition wall 230 separates the end of the first radial flow path 121 near the first fluid entrance hole 2121a from the adjacent circumferential flow paths 114 and 115. In addition, the radial flow path end partition 230 separates the end of the second radial flow path 122 near the second fluid entrance hole 2121b from the adjacent circumferential flow path 114 and 115. When viewed from above, each of the radial flow path end partitions 230 may be provided in a semicircular shape surrounding the first fluid entrance hole 2121a or the second fluid entrance hole 2121b.

The radial partition wall 220 and the radial path end partition wall 230 may have substantially the same thickness as the circumferential partition walls 210. However, an example embodiment of the present disclosure is not limited to this, and the radial partition wall 220 and the radial path end partition wall 230 may have a different thickness from the circumferential partition walls 210.

As described above, when viewed from above, the regions of the flow path 100 become more distinct depending on their distance from the center of the upper surface of the upper body 2110. Therefore, as described in the following embodiments, it is easy to apply different settings to the flow path 100 for each region based on its distance from the center of the upper surface of the upper body 2110.

In addition, the flow path 100 is designed so that fluid flows between the first fluid entrance hole 2121a and the second fluid entrance hole 2121b, moving substantially in a direction from a region farther from the center of the upper surface of the upper body 2110 to a region closer to the center, or in the opposite direction, to cool the substrate 10. According to an example embodiment, the fluid may flow from the first fluid entrance hole 2121a to the second fluid entrance hole 2121b, primarily in a direction from the outer region of the upper body 2110 toward the center. The region near the outer periphery of the upper body 2110 is more exposed to external heat, making it more likely to have a higher temperature than the area adjacent to the center of the upper body 2110. Consequently, the temperature distribution rate of the upper body 2110 can be improved by passing a lower temperature fluid through the area adjacent to the outer periphery of the upper body 2110 than the area adjacent to the center of the upper body 2110.

Additionally, according to an example embodiment, the flow path 100 may be provided as a single path between the first fluid entrance hole 2121a and the second fluid entrance hole 2121b, as illustrated in FIG. 3. The widths of portions of the flow path 100 may be set through simulation or test operations so that the overall flow rate is uniform. On the other hand, when the flow path 100 is divided into several paths, it becomes challenging to maintain a uniform flow rate for each path, which could significantly impact the control of the substrate's 10 temperature distribution. Therefore, as described above, by providing the flow path 100 as a single path with a uniform overall flow rate, the temperature distribution of the substrate 10 may be more easily controlled by adjusting the fluid circulation speed.

In an example embodiment of the present disclosure, at least a part of the peripheral devices 2200 overlap with the flow path 100. For example, a part of the peripheral device 2200 may overlap with a corresponding one of the circumferential flow paths 111 to 118.

A internal element partition 300 surrounds a part of the peripheral device 2200 located on the path of the flow path 100. The internal element partition 300 may isolate the area located on the path of the peripheral device 2200 from the fluid in the flow path 100. A plurality of internal element partitions 300 may be provided with different sizes and positions depending on the number and position of the parts located in the flow path 100 of the peripheral device 2200. Each internal element partition 300 may be provided as a tubular structure surrounding the part located within the flow path 100 of the peripheral device 2200.

According to an example embodiment, parts of the internal element partitions 300 may be provided as parts of the flow path partition 200 when viewed from above. In this case, the parts of the internal element partition 300 provided as the parts of the flow path partition wall 200 may have the same thickness as other parts of the flow path partition wall 200. Accordingly, the parts of the internal element partitions 300 and the parts of the flow path partition wall 200 that overlap each other are designed to have the thickness of a single flow path partition wall 200. This design allows for a larger flow path 100 when viewed from above, compared to the case where the internal element partitions 300 and the flow path partition wall 200 are completely separated.

According to an example embodiment, the internal element partition 300 may include a power connection partition 310, a gas flow path partition 320, and a pin partition 330.

The power connection partition wall 310 surrounds parts passing through the flow path 100 of the electrical connection component, such as the chucking power connection portion 2213 and the heating power connection portion 2223, in the flow path 100. The power connection partition 310 may be provided as a single unit. In this case, the electrical connection component may include a component for transmitting signals, such as the data transmission line 2252 of the temperature measurement portion 2250, in addition to a component for supplying power. In contrast, a plurality of power connection partitions 310 may be provided to respectively correspond to the electrical connection components. Alternatively, some of the power connection partitions 310 are provided to respectively correspond to some electrical connection components, and others of the power connection partitions 310 may surround a plurality of electrical connection components.

A part of the gas supply line 2232 may be formed inside the gas flow path partition 320. In other words, the gas supply line 2232 may extend through the interior of the gas flow path partition 320 and pass through the flow path 100. According to an example embodiment, a plurality of gas flow path partitions 320 may be provided depending on the number of gas supply lines 2232. For example, a plurality of gas flow path partitions 320 may be provided, and the gas flow path partitions 320 may be arranged at regular intervals along the circumferential direction of at least one of the circumferential partition walls 210.

A part of the pin movement path 500 is formed inside the pin partition 330. In other words, the pin movement path 500 may extend through the inside of the pin partition 330 and may pass through the flow path 100. According to an example embodiment, a plurality of pin partitions 330 may be provided depending on the number of lift pins 2241. For example, at least three pin partitions 330 may be arranged at regular intervals along one of the circumferential partition walls 210. The flow path partition wall 200 and the internal element partition 300 may be made of the same material as the lower body 2120.

The flow path partition wall 200 and the internal element partition 300 may be made of the same material as the lower body 2120. According to an example embodiment, the flow path partition wall 200 and the internal element partition 300 may be parts of the lower body 2120, and may be formed together with the lower body 2120 by metal 3D printing.

The substrate treating apparatus 1 may further include various other components (e.g., edge ring, EMI gasket, O-ring, etc.). The vacuum system and various other components of the substrate treating apparatus 1 may vary depending on the plasma generation method and type of process.

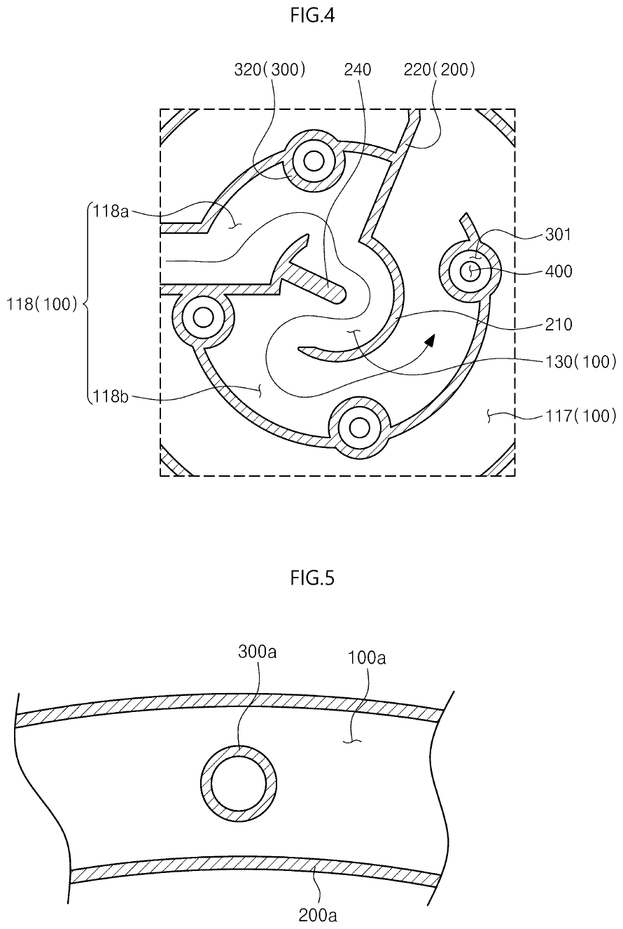

FIG. 4 is an enlarged horizontal cross-sectional view of the center of the stage 2000 illustrated in FIG. 3. Referring to FIG. 4, according to an example embodiment, the circumferential flow path 118 closest to the center flow path 130 may include a first circumferential flow path 118a and a second circumferential flow path 118b. The first circumferential flow path 118a and the second circumferential flow path 118b are arranged along the circumferential direction of the upper surface of the upper body 2110.

One end of the first circumferential flow path 118a may communicate with the end of the second radial flow path 122 farthest from the second fluid entrance hole 2121b. The other end of the first circumferential flow path 118a may communicate with the center flow path 130.

One end of the second circumferential flow path 118b may communicate with another adjacent outer circumferential flow path 117 when viewed from above. The other end of the second circumferential flow path 118b may communicate with the center flow path 130.

According to an example embodiment, the first circumferential flow path 118a and the second circumferential flow path 118b may be combined to form the circumferential flow path 118, which is closest to the center flow path 130. The length of the first circumferential flow path 118a in the circumferential direction may differ from the length of the second circumferential flow path 118b in the circumferential direction. In this case, the section of the circumferential partition wall 210 surrounding the center flow path 130 corresponding to the first circumferential flow path 118a may be shorter than the section corresponding to the second circumferential flow path 118b.

Here, the path forming partition wall 240 may extend from the center of the inner surface of the part corresponding to the first circumferential flow path 118a of the circumferential partition wall 210 directly surrounding the center flow path 130 to the center of the center flow path 130. By providing the path forming partition wall 240, the path of the fluid in the center flow path 130 may be increased, so that the time the fluid stays in the center flow path 130 may be increased. As a result, the center of the substrate 10 may be sufficiently cooled.

According to an example embodiment, the parts overlapping with the flow path 100 of peripheral devices 2200 are in the internal spaces (301 in FIG. 4) of the internal element partition walls 300. For example, a part of the heat transfer gas flow path 400 is formed in the internal space 301 of the gas flow path partition 320. In addition, the part of the chucking power connection portion (2213 in FIG. 2), the part of the heating power connection portion (2223 in FIG. 2) and/or the part of the data transmission line (2252 in FIG. 2) may be accommodated in an internal space of the power connection partition (310 in FIG. 2). Additionally, parts of the lift pins (2241 in FIG. 2) may be accommodated in internal spaces of the pin partitions (330 in FIG. 3).

According to an example embodiment, the thickness of the flow path partition wall 200 may be smaller than the maximum width of the internal space 301 in a direction perpendicular to the side of the flow path partition wall 200. In other words, the thickness of the flow path partition wall 200 may is less than the maximum width of the internal space 301 in a direction perpendicular to the corresponding area of the side of the flow path partition wall 200. For example, the internal element partition 300 and the internal space 301 may be provided as a circular structure when viewed from above. In this case, the flow path partition wall 200 may have a thickness smaller than the diameter of the internal space 301. Accordingly, the parts of the flow path 100 and the parts of the peripheral device 2200 may overlap, thereby the area of the flow path 100 may be increased.

According to an example embodiment, the path forming partition wall 240 may be formed of the same material and by the same manufacturing method as the flow path partition wall 200 and the internal element partition 300 described above.

When the lower body 2120, the flow path partition wall 200, the internal element partition 300 and the path forming partition wall 240 have the same structure as those in FIGS. 2 to 4 and are made of titanium, the thickness of each of these components, including the flow path partition wall 200, the internal element partition 300, and the path forming partition wall 240, may be 0.5 mm or more to withstand the heat and pressure applied when joining the upper body 2110 and the lower body 2120.

The flow path partition wall 200, the internal element partition 300 and the path forming partition wall 240 may be provided with different thicknesses for each region as needed. For example, through test operations or simulation, in areas where the temperature is relatively high, the thicknesses of the flow path partition wall 200, the internal element partition 300, and the path forming partition wall 240 may be set to be small. Similarly, in areas where the temperature is relatively low, the thicknesses of the flow path partition wall 200, the internal element partition 300, and the path forming partition wall 240 may be set to be large. Accordingly, in areas where the thickness of the flow path partition wall 200, the internal element partition 300, and the path forming partition wall 240 are large, the contact area with the fluid may be reduced, so that the temperature may be increased. Additionally, in areas where the thickness of the flow path partition wall 200, the internal element partition 300, and the path forming partition wall 240 are small, the contact area with the fluid may be increased, so that the temperature may be lowered.

According to an example embodiment, when the lower body 2120, the flow path partition wall 200, the internal element partition 300 and the path forming partition wall 240 have the same structure as those in FIGS. 2 to 4 and are made of titanium, to withstand the heat and pressure applied when joining the upper body 2110 and the lower body 2120, the thickness D between the ceiling surface (e.g., top surface) of the flow path 100 and the upper surface of the lower body 2120 may be at 1.5 mm or more. The ratio of the area of the flow path 100 to the area of the upper surface of the body portion 2100 may be 55% or more and 77.75% or less. In this case, if the thickness D between the ceiling surface of the flow path 100 and the upper surface of the lower body 2120 is 1.5 mm, 55% may be the minimum value at which the stage 2000 can cryogenically cool the substrate 10 and maintain the temperature distribution of the substrate. 10. Additionally, 77.75% may be the maximum value when the flow path partition wall 200, the internal element partition 300, and the path forming partition wall 240 have the structures illustrated in FIGS. 2 to 4 and the thickness of 0.5 mm. If the ratio of the area of the flow path 100 to the area of the upper surface of the body portion 2100 is 77.75%, the thickness D between the ceiling surface of the flow path 100 and the upper surface of the lower body 2120 may be at least 2.12 mm.

FIG. 5 is a horizontal cross-sectional view illustrating an internal element partition 300a according to an example embodiment of the present disclosure. Referring to FIG. 5, unlike the case of FIG. 3, when viewed from above, the internal element partition wall 300a may be spaced apart from the flow path partition wall 200a and may be provided in the flow path 100a. In this case, the parts of the peripheral devices disposed inside the internal element partition 330a may penetrate the flow path 100a.

Other features of the internal element partition 300a and the flow path 100a may be the same or similar to the corresponding features of the internal element partition 300 and the flow path 100 of FIG. 3.

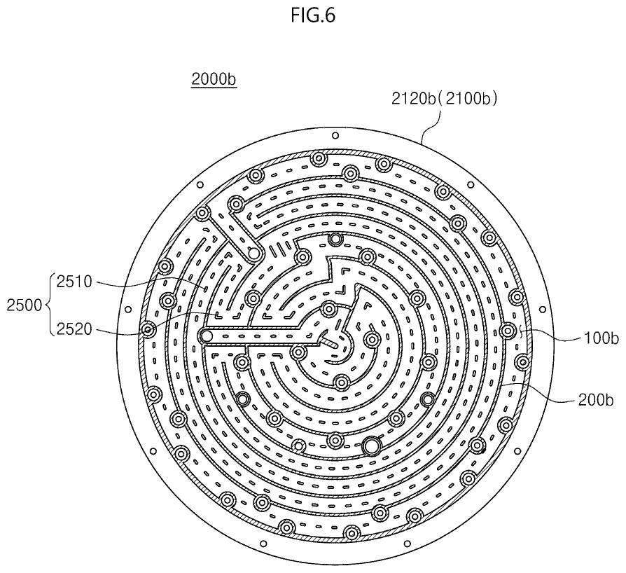

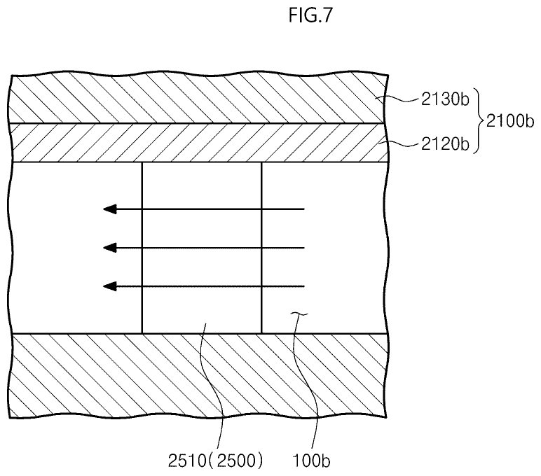

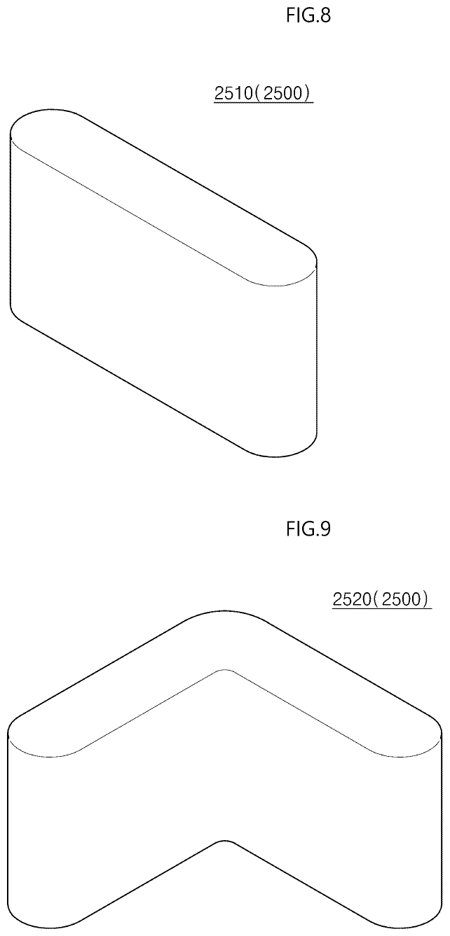

FIG. 6 is a vertical cross-sectional view illustrating an example of a flow path of a stage according to an example embodiment of the present disclosure. FIG. 7 is a vertical cross-sectional view illustrating an example of the heat transfer post illustrated in FIG. 6. FIG. 8 is a perspective view illustrating an example of a first heat transfer post illustrated in FIG. 6. FIG. 9 is a perspective view illustrating an example of a second heat transfer post illustrated in FIG. 6. Referring to FIGS. 6 to 9, the stage 2000b may further include a heat transfer post 2500. The heat transfer post 2500 is provided in the flow path 100b. The heat transfer post 2500 is connected between the ceiling surface and the bottom surface of the flow path 100b. The heat transfer post 2500 may be spaced apart from both sides of the flow path 100b. In other words, the heat transfer post 2500 may be spaced apart from the flow path partition walls 200b that partition the corresponding flow path 100b. The heat transfer post 2500 may be made of a material having a heat transfer rate that is the same as or higher than that of the lower body 2120b. For example, the heat transfer post 2500 may be made of the same material as the lower body 2120b. According to an example embodiment, the heat transfer post 2500 may be provided integrally with the lower body 2120b. For example, the heat transfer post 2500 may be manufactured together with the lower body 2120b using metal 3D printing.

According to an example embodiment, the heat transfer post 2500 may include a first heat transfer post 2510 and a second heat transfer post 2520.

The first heat transfer post 2510 may be provided as a pillar structure having an upper end connected to the ceiling surface of the flow path 100b and a lower end connected to the bottom surface of the flow path 100b. According to an example embodiment, the cross section of the first heat transfer post 2510 cut in the horizontal direction may be a long structure arranged along the path direction of the flow path 100b. For example, the cross-section of the first heat transfer post 2510 cut in the horizontal direction may be a streamlined or oval-shaped structure with a longitudinal direction parallel to the path direction of the flow path 100b. Accordingly, obstruction caused by the first heat transfer post 2510 to the fluid flow may be minimized.

The upper end of the second heat transfer post 2520 may be connected to the ceiling surface of the flow path 100b, and the lower end of the second heat transfer post 2520 may be connected to the bottom surface of the flow path 100b. The second heat transfer post 2520 may include a first portion extending in a first direction and a second portion extending in a second direction. The first direction may be parallel to the upper surface of the lower body 2120b, and the second direction may be parallel to the upper surface of the lower body 2120b and intersect the first direction. According to an example embodiment, the second heat transfer post 2520 may be provided at a location where the flow direction of the fluid changes. For example, the second heat transfer post 2520 may be provided as a plate structure curved to follow the changing flow direction of the fluid at its designated location. The curved plate structure of the second heat transfer post 2520 may include the first portion and the second portion. When viewed from above, the thickness of the second heat transfer post 2520 may gradually decrease from the center of the second heat transfer post 2520 to the end of the first portion, and may gradually decrease from the center of the second heat transfer post 2520 to the end of the second portion. Accordingly, the fluid flow direction may naturally adjust along both sides of the second heat transfer post 2520, minimizing any obstruction to the fluid flow caused by the second heat transfer post 2520.

As described above, by incorporating the heat transfer post 2500, the area available for heat transfer from the body portion 2100b to the fluid is expanded, thereby increasing the heat transfer efficiency between the substrate 10 and the fluid. In an example embodiment, the heat transfer post 2500 may be provided in various structures as needed.

Other features of the stage 2000b may be the same or similar to the corresponding features of the stage 2000 of FIG. 3. The corresponding features or elements in FIGS. 6-9 may be denoted with a ‘b’.

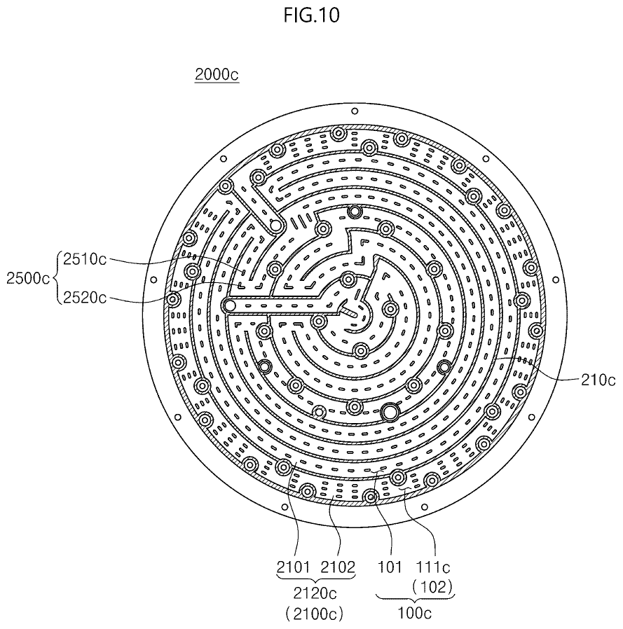

FIG. 10 is a horizontal cross-sectional view illustrating an example of a flow path of a stage according to an example embodiment of the present disclosure.

Referring to FIG. 10, according to an example embodiment, the body portion 2100c may include a central area 2101 and an edge area 2102.

The central area 2101 may include the center of the body portion 2100c and an area surrounding the center when viewed from above. The edge area 2102 may be an area located outside the central area 2101 when viewed from above. The edge area 2102 may be provided in a ring shape surrounding the central area 2101. According to an example embodiment, when the radius of the substrate 10 is 150 mm, the central area 2101 may correspond to an area of the substrate 10 with a radius of less than 130 mm, and the edge area 2102 may correspond to an area of the substrate 10 with a radius of 130 mm or more.

The flow path 100c may include a central flow path 101 and an edge flow path 102. When viewed from above, the central flow path 101 may be formed in the central area 2101. The edge flow path 102 may be formed in the edge area 2102. According to an example embodiment, depending on the located radius, some of the circumferential flow paths 111c may be provided as the edge flow paths 102, and other flow paths among the flow paths 100c may be provided as the central flow paths 101. In this case, one of the circumferential partition walls 210c may be located between the edge flow paths 102 and the central flow paths 101. In other words, one of the circumferential partition walls 210c may be located at a radial position of 130 mm from the center of the substrate 10.

When viewed from above, the number of heat transfer posts 2500c per unit area in the edge flow path 102 may be greater than the number of heat transfer posts 2500c per unit area in the central flow path 101. For example, the first heat transfer post 2510c and the second heat transfer post 2520c located in the central flow path 101 may be arranged in a line along the path direction of the flow path 100c. The first heat transfer posts 2510c located in the edge flow path 102 may be spaced apart from each other along a direction perpendicular to the path direction of the edge flow path 102. In other words, the first heat transfer posts 2510c located within the edge flow path 102 may be arranged in a plurality of rows along the path direction of the edge flow path 102. In contrast, the heat transfer posts 2500c may be arranged in the same number of rows along the path direction of the flow path 100c. In this case, the spacing between the heat transfer posts 2500c located in the edge flow path 102 may be narrower than the spacing between the heat transfer posts 2500c positioned in the central flow path 101.

Accordingly, the heat at the edge area of the substrate 10, where the heat of the processing space 1100 is more easily transferred, is more easily transferred to the fluid than the heat at the central area of the substrate 10, thereby the temperature distribution of the substrate 10 may be improved.

Other features of the stage 2000c may be the same or similar to the corresponding features of the stage 2000b of FIGS. 6 to 9 described above. The corresponding features or elements in FIG. 10 may be denoted with a ‘c’.

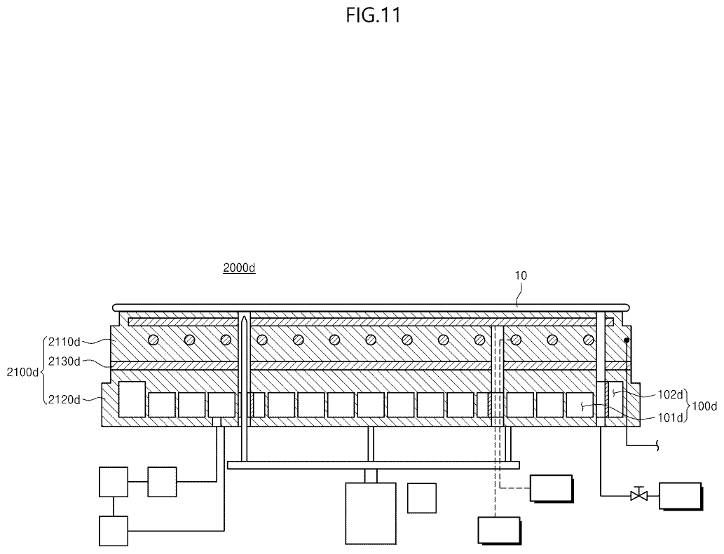

FIG. 11 is a vertical cross-sectional view illustrating a stage 2000d according to an example embodiment of the present disclosure. Referring to FIG. 11, the upper surface of the body portion 2100d on which the substrate 10 is placed may be flat. The heights of the ceiling surfaces of at least some of the flow paths 100d may be different depending on their location. In other words, the thickness between the ceiling surface of the flow path 100d and the top surface of the body portion 2100d may vary depending on their location. For example, through test operations or simulation, the height of the ceiling surface of a relatively higher temperature area of the flow path 100d may be set high, and the height of the ceiling surface of a relatively lower temperature area of the flow path 100d may be set low. According to an example embodiment, the ceiling surface of the central flow path 101d may be lower than the ceiling surface of the edge flow path 102d. Therefore, the varying distance between the ceiling surface of the flow path 100d and the substrate 10 across different areas allows for improved temperature distribution of the substrate 10. This is achieved by increasing the heat conduction efficiency with the fluid in the area adjacent to the outer periphery of the substrate 10 which tends to have a higher temperature than central of the substrate 10 because of greater exposure to external heat.

Other features of the stage 2000d may be the same or similar to those of the stage 2000 of FIG. 3. The corresponding features or elements in FIG. 11 may be denoted with a ‘d’.

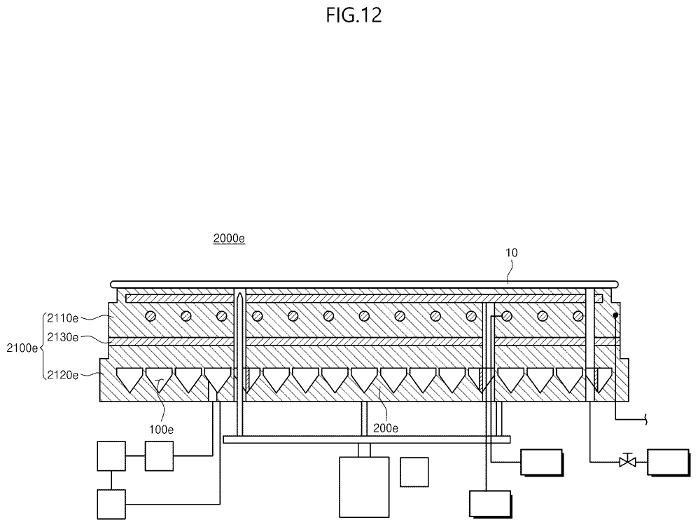

FIG. 12 is a vertical cross-sectional view illustrating a stage according to an example embodiment of the present disclosure. Referring to FIG. 12, when viewed in the length direction of the path of the flow path 100e, the flow path 100e may include areas where both sides slope toward each other from the top downward. For example, when viewed along the path direction of the flow path 100e, at least a part of the flow path 100e may have an inverted triangular structure from the bottom. Accordingly, the flow path partition wall 200e may include areas where both sides slope toward each other from the bottom upward. Therefore, the lower body 2120e and the components provided integrally with the lower body 2120e may be more suitable for manufacturing by metal 3D printing, which is a method of printing by stacking materials from below.

Other features of the stage 2000e may be the same or similar to those of the stage 2000 of FIG. 3. The corresponding features or elements in FIG. 12 may be denoted with an ‘e’.

As described above, the flow path does not bypass the peripheral device, and at least part of the peripheral device is positioned along the flow path. This allows the stage and the substrate treating apparatus, according to embodiments of the present disclosure, to expand the area of the flow path when viewed from above.

Therefore, the expanded flow path area enables the stage and the substrate treating apparatus, according to embodiments of the present disclosure, to increase the heat transfer rate between the flow path inside the stage and the substrate, and improve the temperature distribution of the substrate.

Embodiments of the present disclosure provide a stage that may increase the heat transfer rate between a flow path therein and a substrate, and a substrate treating apparatus including the same.

Embodiments of the present disclosure provide a stage that may improve temperature distribution of a substrate and a substrate treating apparatus including the same. While the present disclosure has been described with reference to embodiments thereof, it

will be apparent to those of ordinary skill in the art that various changes and modifications can be made thereto without departing from the spirit and scope of the present disclosure as set forth in the following claims.

What is claimed is:

1. A stage comprising:
a body portion configured to support a substrate, wherein the body portion includes a flow path; and
a peripheral device, at least a part of which is located inside the body portion,
wherein the part of the peripheral device is positioned at the same height as the flow path and overlaps the flow path when viewed from above,
wherein the flow path is partitioned by a flow path partition wall,
wherein the part of the peripheral device is surrounded by an internal element partition and included within an internal space of the internal element partition,
wherein a thickness of the flow path partition wall is smaller than a maximum width of the internal space in a direction perpendicular to a side of the flow path partition wall.

2. The stage of claim 1,
wherein the flow path includes a plurality of circumferential flow paths extending along a circumferential direction of an upper surface of the body portion,
wherein the plurality of circumferential flow paths are partitioned by circumferential partition walls,
wherein each of the circumferential partition walls has a uniform thickness.

3. The stage of claim 1, wherein the body portion includes:
an upper body directly supporting the substrate; and
a lower body provided below the upper body,
wherein the flow path is in the lower body.

4. The stage of claim 1 further comprising:
a heat transfer post provided in the flow path and connected between a top surface and a bottom surface of the flow path.

5. The stage of claim 4, wherein the heat transfer post is spaced apart from at least one side of the flow path.

6. The stage of claim 4,
wherein the body portion includes:
a central area that includes a central portion of the body portion and an area surrounding the central portion, when viewed from above; and
an edge area located outside the central area,
wherein the flow path includes:
a central flow path in the central area; and
an edge flow path in the edge area,
wherein the heat transfer post is provided in plural, and the heat transfer posts are provided in a greater number per unit area in the edge flow path than in the central flow path.

7. The stage of claim 1,
wherein the body portion includes:
a central area that includes a central portion of the body portion and an area surrounding the central portion, when viewed from above; and
an edge area located outside the central area,
wherein the flow path includes:
a central flow path in the central area; and
an edge flow path in the edge area,
wherein a top surface of the central flow path is lower than a top surface of the edge flow path.

8. The stage of claim 1, wherein a fluid in the flow path is a cryogenic refrigerant.

9. The stage of claim 1, wherein the flow path includes areas on both sides, when viewed along a longitudinal direction of the flow path, that slope toward each other from an upper surface downward.

10. A substrate treating apparatus comprising:
a chamber in which a processing space for processing a substrate is formed; and
a stage configured to support a substrate in the processing space,
wherein the stage includes:
a body portion configured to place the substrate on an upper surface thereof, wherein the body portion includes a flow path; and
a peripheral device, at least a part of which is located inside the body portion,
wherein the part of the peripheral device is positioned at the same height as the flow path and overlaps the flow path when viewed from above,
wherein the flow path is partitioned by a flow path partition wall,
wherein the part of the peripheral device is surrounded by an internal element partition and included within an internal space of the internal element partition,
wherein a thickness of the flow path partition wall is smaller than a maximum width of the internal space in a direction perpendicular to a side of the flow path partition wall.

11. The substrate treating apparatus of claim 10,
wherein the flow path includes a plurality of circumferential flow paths extending along a circumferential direction of an upper surface of the body portion,
wherein the plurality of circumferential flow paths are partitioned by circumferential partition walls,
wherein each of the circumferential partition walls has a uniform thickness.

12. The substrate treating apparatus of claim 10, wherein the stage further includes a heat transfer post provided in the flow path and connected between a top surface and a bottom surface of the flow path.

13. The substrate treating apparatus of claim 12, wherein the heat transfer post is spaced apart from at least one side of the flow path.

14. The substrate treating apparatus of claim 12,
wherein the body portion includes:
a central area that includes a central portion of the body portion and an area surrounding the central portion, when viewed from above; and
an edge area located outside the central area,
wherein the flow path includes:
a central flow path in the central area; and
an edge flow path in the edge area,
wherein the heat transfer post is provided in plural, and the heat transfer posts are provided in a greater number per unit area in the edge flow path than in the central flow path.

15. The substrate treating apparatus of claim 10,
wherein the body portion includes:
a central area that includes a central portion of the body portion and an area surrounding the central portion, when viewed from above; and
an edge area located outside the central area,
wherein the flow path includes:
a central flow path in the central area; and
an edge flow path in the edge area,
wherein a top surface of the central flow path is lower than a top surface of the edge flow path.

16. A substrate treating apparatus comprising:
a chamber in which a processing space for processing a substrate is formed;
a stage configured to support a substrate in the processing space; and
a treating fluid supply portion configured to supply a treating fluid for processing the substrate to the processing space,
wherein the stage includes:
a body portion configured to place a substrate on an upper surface thereof, wherein the body portion includes a flow path; and
a peripheral device, at least a part of which is located inside the body portion,
wherein the part of the peripheral device is positioned at the same height as the flow path and overlaps the flow path when viewed from above,
wherein the flow path is partitioned by a flow path partition wall,
wherein the part of the peripheral device is surrounded by an internal element partition and included within an internal space of the internal element partition,
wherein a thickness of the flow path partition wall is smaller than a maximum width of the internal space in a direction perpendicular to a side of the flow path partition wall.

17. The substrate treating apparatus of claim 16,
wherein the flow path includes a plurality of circumferential flow paths extending along a circumferential direction of the upper surface of the body portion,
wherein the plurality of circumferential flow paths are partitioned by circumferential partition walls,
wherein each of the circumferential partition walls has a uniform thickness.

18. The substrate treating apparatus of claim 16, wherein the stage further includes a heat transfer post provided in the flow path and connected between a top surface and a bottom surface of the flow path.

19. The substrate treating apparatus of claim 18, wherein the heat transfer post is spaced apart from at least one side of the flow path.

20. The substrate treating apparatus of claim 18,
wherein the body portion includes:
a central area that includes a central portion of the body portion and an area surrounding the central portion, when viewed from above; and
an edge area located outside the central area,
wherein the flow path includes:
a central flow path in the central area; and
an edge flow path in the edge area,
wherein the heat transfer post is provided in plural, and the heat transfer posts are provided in a greater number per unit area in the edge flow path than in the central flow path.
